(19) United States
(12) Patent Application Publication
(10) Pub. No.: US 2013/0002101 A1
(43) Pub. Date: Jan. 3, 2013

(54) HOUSING AND ELECTRONIC DEVICE USING THE SAME

(75) Inventor: Li-Wei Liu, New Taipei City (TW)

(73) Assignee: WISTRON CORPORATION, New Taipei City (TW)

(21) Appl. No.: 13/369,613

(22) Filed: Feb. 9, 2012

(30) Foreign Application Priority Data
Jun. 28, 2011 (TW) 100122643

(51) Int. Cl. H05K 5/02

(52) U.S. Cl. 312/222

(57) ABSTRACT

A housing used in an electronic device includes a first casing, a second casing, a key, a latch and an elastic member. The key coupled to the first casing has a first inclined surface. The latch coupled to the first casing has a second inclined surface so as to be engaged with the second casing at a first position or release the second casing at a second position. When a force is applied to the key to move the key along a first direction, the first inclined surface pushes the second inclined surface, so that the latch is moved from the first position to the second position to release the second casing and deform the elastic member. When no force is applied to the key, the elastic member drives the latch towards the first position, and the second inclined surface pushes the first inclined surface to move the key.

This application claims the benefit of Taiwan application Serial No. 100122643, filed Jun. 28, 2011, the subject matter of which is incorporated herein by reference.

### BACKGROUND OF THE INVENTION

1. Field of the Invention

The invention relates in general to a housing and an electronic device using the same, and more particularly to a housing with detachable casing and an electronic device using the same.

2. Description of the Related Art

Along with the rapid advance, the electronic devices having gained a large popularity indeed bring convenience to users' everyday life. To make the users' life more versatile and creative, more and more electronic device are directed towards personalized design. For example, a portion of the electronic device provides different casings for the users to replace according to their likes to highlight personal preference and add lots of fun to the use. Currently, the replacement mechanism of a portion of casings is implemented by the key and a large number of springs. Or, in an alternate replacement mechanism, the engaging member is driven by a key to engage or release the casing. However, the above methods all involve difficult assembly and high manufacturing costs. It has become an important task for the industries to provide an electronic device with an easy-to-replace casing, and the requirements of less assemble difficulty and lower manufacturing cost are still satisfiable.

### SUMMARY OF THE INVENTION

The invention is directed to a housing and an electronic device using the same. Through the cooperation of a key, a latch and an elastic member, the first casing and the second casing can be disposed in a detachable manner. Thus, the user can decide whether to replace the second casing according to actual needs. Moreover, the housing and the electronic device using the same of the invention have the advantages of easy assembly and low manufacturing costs.

According to one embodiment of the present invention, a housing including a first casing, a second casing, a key, a latch and an elastic member is provided. The second casing is disposed outside the first casing. The key is movably coupled to the first casing and has at least one first inclined surface. The latch is movably coupled to the first casing and has at least one second inclined surface so as to be engaged with the second casing at a first position or release the second casing at a second position. Two ends of the elastic member are coupled to the first casing and the latch, respectively. When a force is applied to the key to move the key along a first direction, the first inclined surface of the key pushes the second inclined surface of the latch, so that the latch is moved from the first position to the second position to release the second casing and make the elastic member elastically deformed. When the key stops receiving the force, the elastic member drives the latch to move from the second position towards the first position, so that the second inclined surface of the latch pushes the first inclined surface of the key to move the key along a second direction opposite to the first direction.

According to an alternate embodiment of the present invention, an electronic device including a machine body is provided. The machine body includes a housing. The housing includes a first casing, a second casing, a key, a latch and an elastic member. The second casing is disposed outside the first casing. The key is movably coupled to the first casing and has at least one first inclined surface. The latch is movably coupled to the first casing and has at least one second inclined surface so as to be engaged with the second casing at a first position or release the second casing at a second position. Two ends of the elastic member are coupled to the first casing and the latch, respectively. When a force is applied to the key to move the key along a first direction, the first inclined surface of the key pushes the second inclined surface of the latch, so that the latch is moved from the first position to the second position to release the second casing and make the elastic member elastically deformed. When the key stops receiving the force, the elastic member drives the latch to move from the second position towards the first position, so that the second inclined surface of the latch pushes the first inclined surface of the key to move the key along a second direction opposite to the first direction.

The above and other aspects of the invention will become better understood with regard to the following detailed description of the non-limiting embodiment(s). The following description is made with reference to the accompanying drawings.

### BRIEF DESCRIPTION OF THE DRAWINGS

FIG. 1A shows an explosion diagram of a housing according to the first embodiment of the invention;

FIG. 1B shows a partial enlargement of the housing of FIG. 1A;

FIG. 2-FIG. 4 are top views of the housing FIG. 1B in different movement states during assembly;

FIG. 5 shows a schematic diagram of the key and the first casing of FIG. 1B;

FIG. 6 shows a schematic diagram of the key of FIG. 1B;

FIG. 7 shows a schematic diagram of a housing according to the second embodiment of the invention;

FIG. 8 shows a schematic diagram of an electronic device according to the third embodiment of the invention.

### DETAILED DESCRIPTION OF THE INVENTION

### First Embodiment

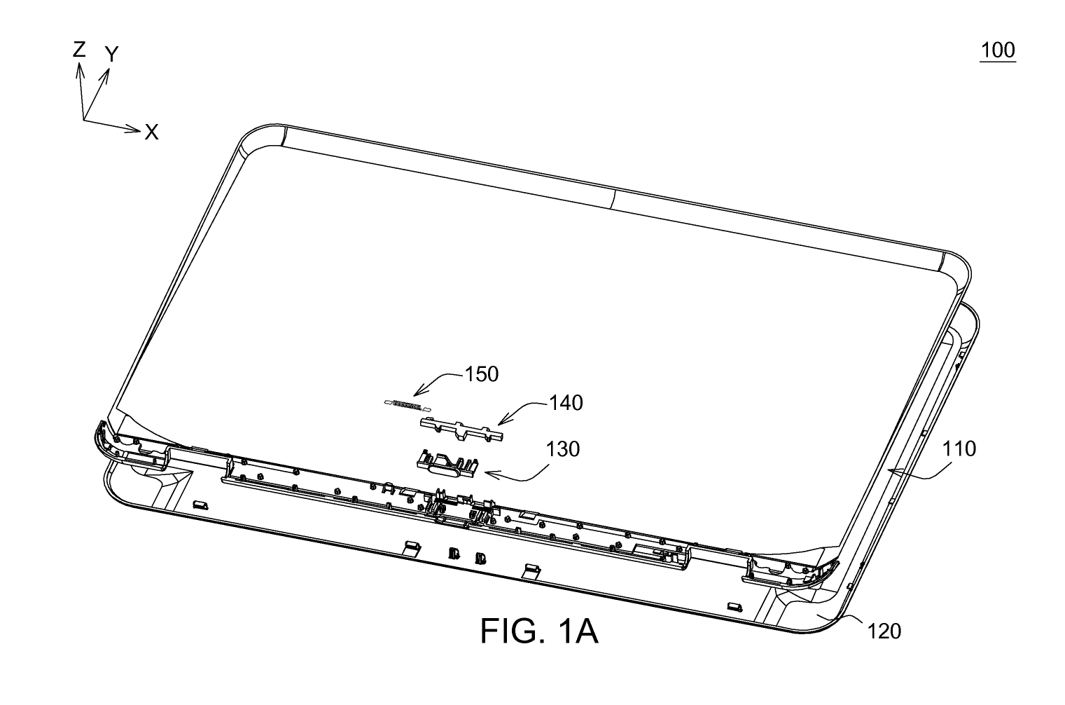

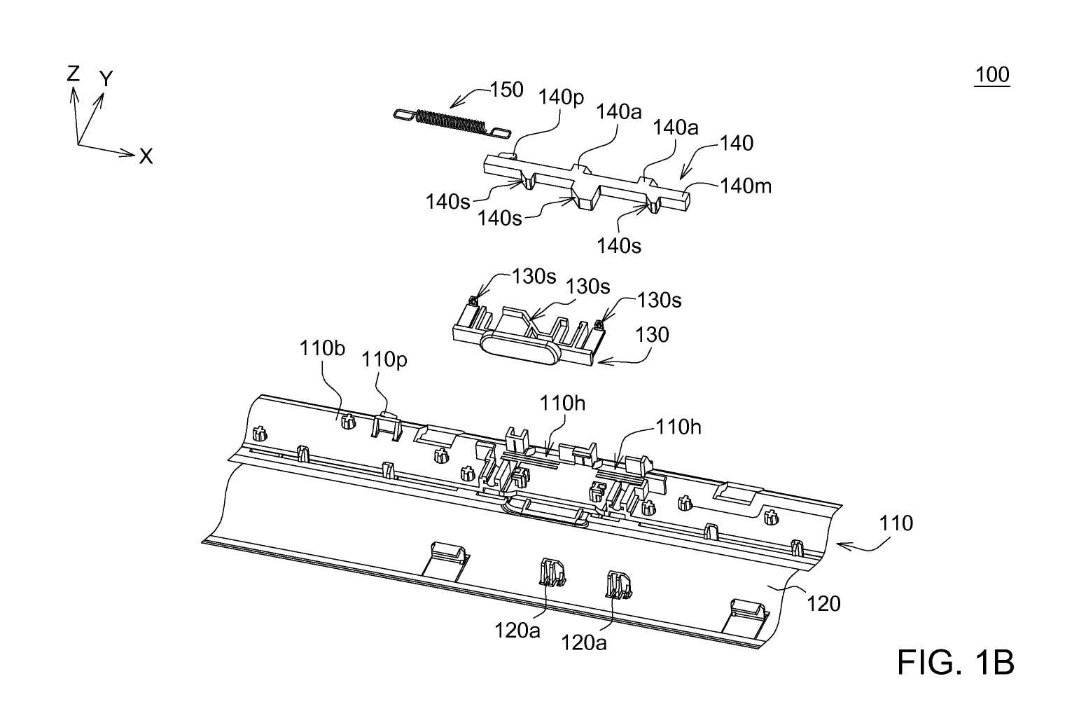

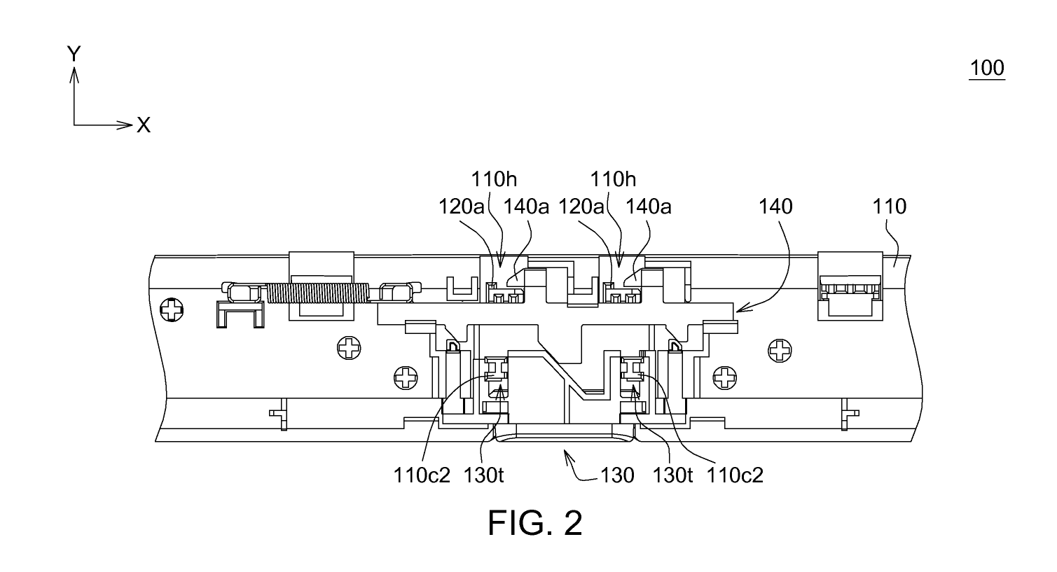

Referring to FIGS. 1A and 1B and FIG. 2-FIG. 4. FIG. 1A shows an explosion diagram of a housing according to the first embodiment of the invention. FIG. 1B shows a partial enlargement of the housing of FIG. 1A. FIG. 2-FIG. 4 are top views of the housing FIG. 1B in different movement states during assembly.

The housing 100 includes a first casing 110, a second casing 120, a key 130, a latch 140 and an elastic member 150. The second casing 120 is disposed outside the first casing 110. The key 130 is movably coupled to the first casing 110 and has at least one first inclined surface 130s. The latch 140 is movably coupled to the first casing 110 and has at least one second inclined surface 140s. Two ends of the elastic member 150 are coupled to the first casing 110 and the latch 140, respectively.

The assembly of the first casing 110, the second casing 120 and the latch 140 of the present embodiment of the invention is elaborated first. However, anyone who is skilled in the technology of the invention would understand that the assembly of the first casing 110, the second casing 120 and the latch 140 is not limited to the exemplification disclosed here. As indicated in FIG. 1B and FIG. 2, the first casing 110 has at least one through hole 110h, the second casing 120 has at least one first engaging member 120a, and the latch 140 has at least one second engaging member 140a. The second engaging member 140a of the latch 140 located at the first position is engaged with the first engaging member 120a of the second casing 120 passing through the through hole 110h. Thus, the first casing 110 and the second casing 120 are assembled together through the latch 140.

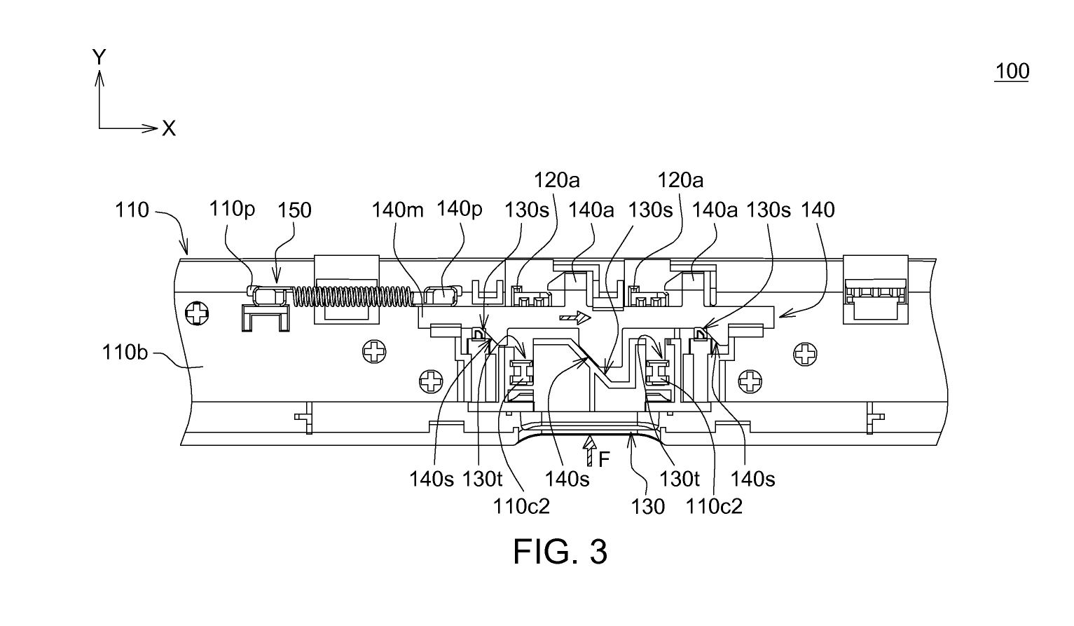

Relative dispositions and relationships of the elements in operations are exemplified by the assembly of the first casing 110, the second casing 120 and the latch 140 of the present embodiment of the invention. As indicated in FIG. 1B and FIG. 3, when the key 130 receives a force F and moves along a first direction (such as the +Y-axis direction), the first inclined surface 130s of the key 130 pushes the second inclined surface 140s of the latch 140, so that the latch 140 is moved along the +X-axis direction. That is, the latch 140 is moved from the first position of FIG. 2 to the second position of FIG. 3 to lift the engagement between the second engaging member 140a and the first engaging member 120a so as to release the second casing 120 and make the elastic member 150 elastically deformed. Thus, the user can detach and replace the second casing 120.

In an embodiment, the elastic member 150 could be an extension spring. Thus, the latch 140, when at the second position, stretches the elastic member 150 and makes the elastic member 150 elastically deformed. In order to fix the extension spring (as being the elastic member 150), the first casing 110 has a main member 110b and a first hook 110p which are mutually connected to each other, and the latch 140 has a main body 140m and the second hook 140p which are mutually connected to each other. Two ends of the elastic member 150 are mounted on the first hook 110p and the second hook 140p, respectively. During the operations, since the first hook 110p and the second hook 140p are mainly a force receiving structure, the connection between the first hook 110p and the main member 110b, and the connection between the second hook 140p and the main body 140m would be likely broken. To avoid the connections being broken, the connection between the first hook 110p and the main member 110b has an arced surface for increasing the area and range of the connection between the first hook 110p and the main member 110b and also enhancing the intensity of the connection, accordingly. Likewise, the connection between the second hook 140p and the main body 140m has an arced surface, so that the area and range of the connection between the second hook 140p and the main body 140m are increased and the intensity of the connection is enhanced accordingly.

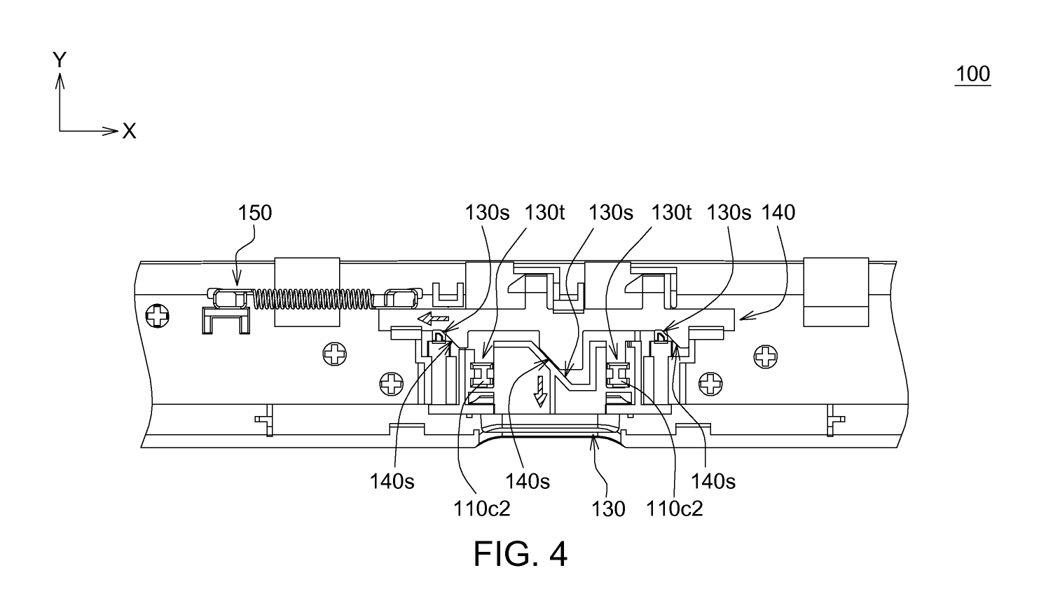

As indicated in FIG. 1B and FIG. 4, when the key 130 stops receiving the force F, the restoring force of spring enables the elastic member 150 to drive the latch 140 to move towards the −X-axis direction. That is, the latch 140 is moved from the second position towards the first position, so that the second inclined surface 140s of the latch 140 pushes the first inclined surface 130s of the key 130 to move the key 130 along a second direction (that is, the −Y-axis direction) opposite to the first direction. Thus, the key 130 can be moved back to the original position.

In the present embodiment, the latch 140 is moved between the first position and the second position in a direction (that is, the X-axis direction) substantially perpendicular to the first direction (that is, the +Y-axis direction). In other words, through the disposition of the first inclined surface 130s and the second inclined surface 140s, the operation directions of the key 130 and the latch 140 are convertible, so that the key 130 can be moved towards the +Y-axis direction to drive the latch 140 to move along the +X-axis direction, and the latch 140 can be moved towards the −X-axis direction to move the key 130 towards the −Y-axis direction.

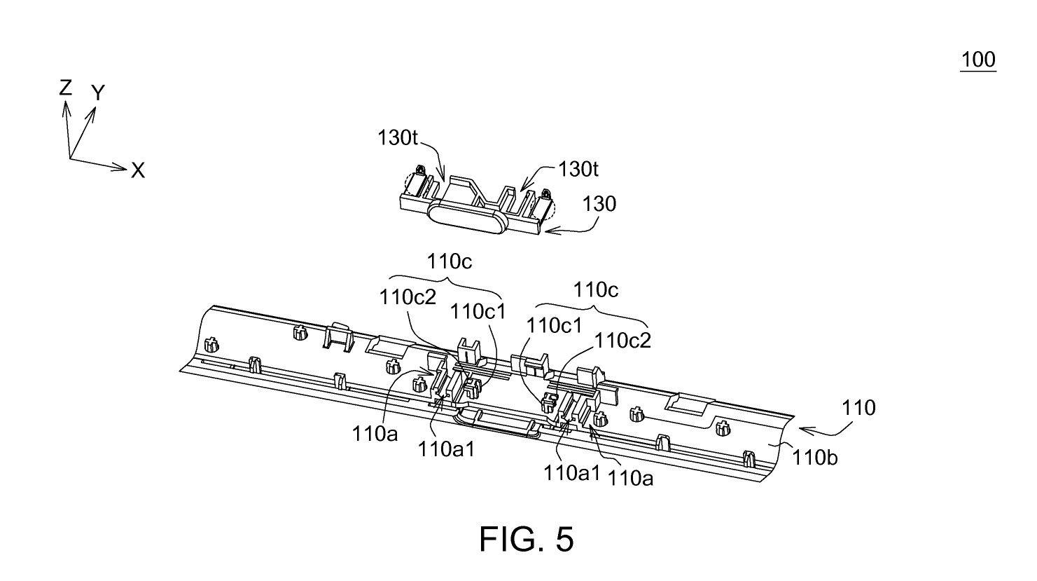

Referring to FIG. 2-FIG. 5. FIG. 5 shows a schematic diagram of the key and the first casing of FIG. 1B. To increase the stability of the key 130 and the first casing 110 in the Z-axis direction during assembly, the key 130 has a recess 130t, and the first casing 110 has a blocker 110c. The blocker 110c has a connection member 110c1 and a stopper member 110c2. The connection member 110c1 is connected to the main member 110b and passes through recess 130t. The stopper member 110c2 is extended to the key 130 from the connection member 110c1 passing through recess 130t to restrict the displacement of the key 130 in the Z-axis direction.

As indicated in FIG. 5, the first casing 110 has a stopper structure 110a. The stopper structure 110a has a slide groove 110a1 extended along a first direction (that is, the +Y-axis direction). The portion of the key 130 (circled in dotted lines) is embedded in the slide groove 110a1, so that the key 130 is moved along the movement direction only (that is, the Y-axis direction). In other words, through the disposition of the stopper structure 110a, the key 130 cannot be moved along the Z-axis direction or the X-axis direction.

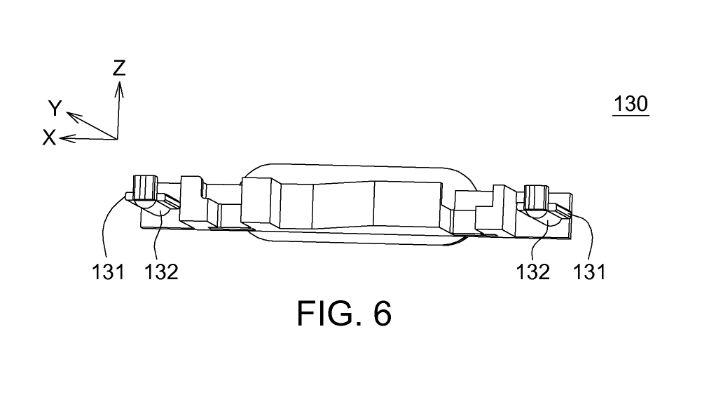

Referring to FIG. 5 and FIG. 6. FIG. 6 shows a schematic diagram of the key of FIG. 1B. The portion of the key 130 circled in dotted lines has a plate 131 and an arced protrusion 132 protruded from the plate 131. The silhouette of the slide groove corresponds to that of the plate 131 and the arced protrusion 132, so that the efficiency and convenience during the assembly can be further increased through the reduction in friction.

### Second Embodiment

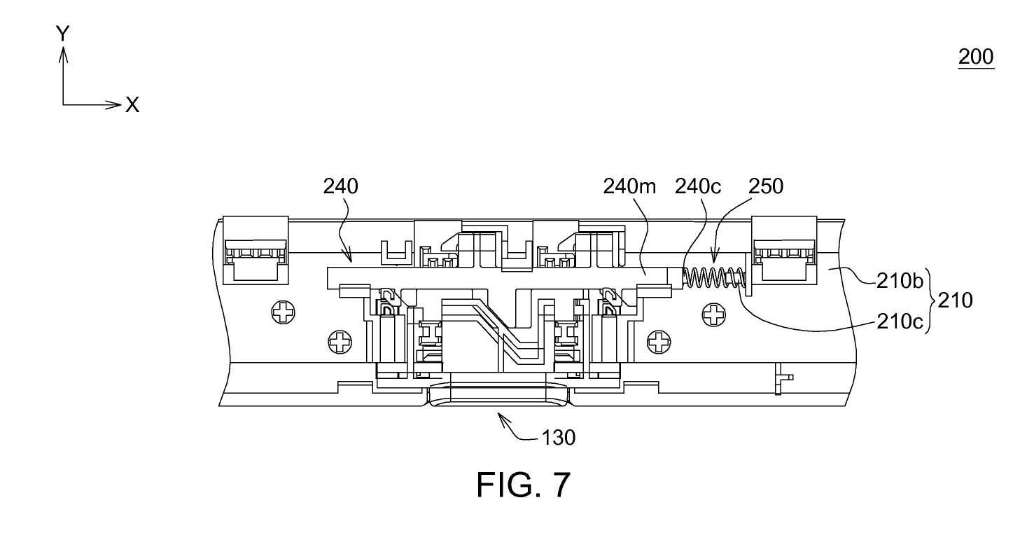

Referring to FIG. 7, a schematic diagram of a housing according to the second embodiment of the invention is shown. The present embodiment of the invention is different from the first embodiment in the elastic member 250 of the housing 200. Other elements and dispositions similar to the first embodiment are not repeatedly described here.

In the present embodiment, the elastic member 250 is realized by such as a compression spring. The latch 240, when at the second position, compresses the elastic member 250 and makes the elastic member 250 elastically deformed. The first casing 210 has a main member 210b and a first cylinder 210c which are mutually connected to each other, and the latch 240 has a main body 240m and a second cylinder 240c which are mutually connected to each other. Two ends of the elastic member 250 are respectively mounted on the first cylinder 210c and the second cylinder 240c for providing the function similar to that provided by the elastic member 150 of the first embodiment. Thus, the advantages of the housing 200 of the present embodiment of the invention are similar to that of the housing 100 of the first embodiment.

### Third Embodiment

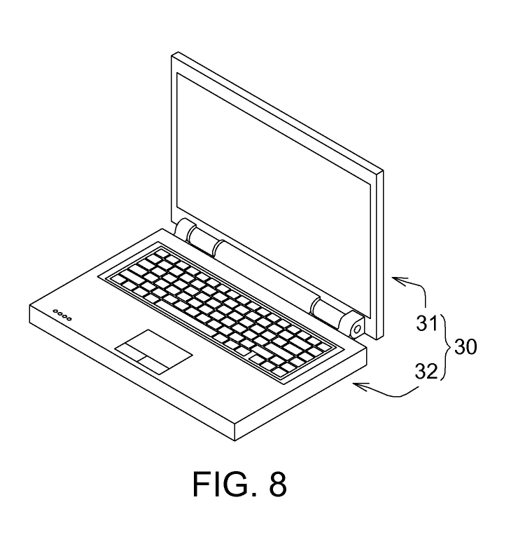

Referring to FIG. 8, a schematic diagram of an electronic device according to the third embodiment of the invention is shown. The electronic device 30, such as a laptop, includes a machine body 31 and a machine body 32. Examples of the machine body 31 include the housing 100 of FIG. 1A (the first embodiment) and the housing 200 of FIG. 7 (the second embodiment), so that the second casing can be detachably disposed to the first casing through the cooperation of the elastic member and the latch. However, anyone who is skilled in the technology of the invention will understand that despite the electronic device 30 is exemplified by a laptop, the electronic device 30 can also be realized by other devices with housing, such as a mobile phone or a personal digital assistant.

According to the housing and the electronic device using the same disclosed in the above embodiments of the invention, a first casing and a second casing can be disposed in a detachable manner through the disposition of a key, a latch and an elastic member. Since the first casing and the second casing can be disposed in a detachable manner, the user can decide whether to replace the second casing according to actual needs. In the above embodiments, the housing uses only one elastic member for driving the latch to move towards the original position, thereby moving the key. Therefore, the housing has the advantages of easy assembly and low manufacturing cost.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A housing, comprising:
a first casing;
a second casing disposed outside the first casing;
a key movably coupled to the first casing and having at least one first inclined surface;
a latch movably coupled to the first casing and having at least one second inclined surface so as to be engaged with the second casing at a first position or release the second casing at a second position; and
an elastic member with two ends coupled to the first casing and the latch, respectively;
wherein, when a force is applied to the key to move the key along a first direction, the at least one first inclined surface of the key pushes the at least one second inclined surface of the key, so that the latch is moved from the first position to the second position to release the second casing and make the elastic member elastically deformed;
wherein, when the key stops receiving the force, the elastic member drives the latch to move from the second position towards the first position, so that the at least one second inclined surface of the key pushes the at least one first inclined surface of the key to move the key along a second direction opposite to the first direction.

2. The housing accordingly 1, wherein the first casing has at least one through hole, the second casing has at least one first engaging member, the latch has at least one second engaging member, and the at least one second engaging member of the latch located at the first position is engaged with the at least one first engaging member of the second casing passing through the at least one through hole.

3. The housing accordingly 1, wherein the first casing has a stopper structure, the stopper structure has a slide groove extended along a first direction, and a portion of the key is embedded in the slide groove, so that the key only moves in the first direction.

4. The housing accordingly 3, wherein the portion of the key has a plate and an arced protrusion protruded from the plate, and the silhouette of the slide groove corresponds to that of the plate and the arced protrusion.

5. The housing accordingly 1, wherein the key has a recess, the first casing has a main member and a blocker, the blocker has a connection member and a stopper member, the connection member is connected to the main member and passes through the recess, and the stopper member is extended to the key from the connection member passing through the recess.

6. The housing accordingly 1, wherein the latch moves between the first position and the second position in a direction substantially perpendicular to the first direction.

7. The housing accordingly 1, wherein the elastic member is an extension spring, and the latch stretches the elastic member when the latch is at the second position.

8. The housing accordingly 7, wherein the first casing has a main member and a first hook which are mutually connected to each other, the latch has a main body and a second hook which are mutually connected to each other, and two ends of the elastic member are mounted on the first hook and the second hook, respectively.

9. The housing accordingly 8, wherein the connection between the first hook and the main member has an arced surface.

10. The housing accordingly 8, wherein the connection between the second hook and the main body has an arced surface.

11. The housing accordingly 1, wherein the elastic member is a compression spring, and the latch compresses the elastic member when the latch is at the second position.

12. The housing accordingly 11, wherein the first casing has a main member and a first cylinder which are mutually connected to each other, the latch has a main body and a second cylinder which are mutually connected to each other, and two ends of the elastic member are mounted on the first cylinder and the second cylinder, respectively.

13. An electronic device, comprising:
a machine body, comprises:
a housing, comprising:
a first casing;
a second casing disposed outside the first casing;
a key movably coupled to the first casing and having at least one first inclined surface;
a latch movably coupled to the first casing and having at least one second inclined surface so as to be engaged with the second casing at a first position or release the second casing at a second position; and
an elastic member with two ends coupled to the first casing and the latch, respectively;
wherein, when a force is applied to the key to move the key along a first direction, the at least one first inclined surface of the key pushes the at least one second inclined surface of the key, so that the latch is moved from the first position to the second position to release the second casing and make the elastic member elastically deformed;
wherein, when the key stops receiving the force, the elastic member drives the latch to move from the second position towards the first position, so that the at least one second inclined surface of the key pushes the at least one first inclined surface of the key to move the key along a second direction opposite to the first direction.

14. The electronic device accordingly 13, wherein the first casing has at least one through hole, the second casing has at least one first engaging member, the latch has at least one second engaging member, and the at least one second engaging member of the latch located at the first position is engaged with the at least one first engaging member of the second casing passing through the at least one through hole.

15. The electronic device accordingly 13, wherein the first casing has a stopper structure, the stopper structure has a slide groove extended along a first direction, and a portion of the key is embedded in the slide groove, so that the key only moves in the first direction;
wherein the portion of the key has a plate and an arced protrusion protruded from the plate, and the silhouette of the slide groove corresponds to that of the plate and the arced protrusion.

16. The electronic device accordingly 13, wherein the key has a recess, the first casing has a main member and a blocker, the blocker has a connection member and a stopper member, the connection member is connected to the main member and passes through the recess, and the stopper member is extended to the key from the connection member passing through the recess.

17. The electronic device accordingly 13, wherein the latch moves between the first position and the second position in a direction substantially perpendicular to the first direction.

18. The electronic device accordingly 13, wherein the elastic member is an extension spring, and the latch stretches the elastic member when the latch is at the second position;
wherein the first casing has a main member and a first hook which are mutually connected to each other, the latch has a main body and a second hook which are mutually connected to each other, and two ends of the elastic member are mounted on the first hook and the second hook, respectively.

19. The electronic device accordingly 18, wherein the connection between the first hook and the main member has an arced surface, and the connection between the second hook and the main body has an arced surface.

20. The electronic device accordingly 13, wherein the elastic member is a compression spring, and the latch compresses the elastic member when the latch is at the second position;
wherein the first casing has a main member and a first cylinder which are mutually connected to each other, the latch has a main body and a second cylinder which are mutually connected to each other, and two ends of the elastic member are mounted on the first cylinder and the second cylinder, respectively.
